(19) United States
(12) Patent Application Publication
(10) Pub. No.: US 2025/0391722 A1
(43) Pub. Date: Dec. 25, 2025

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Keiichi NIWA, Yokkaichi Mie (JP)

(73) Assignee: Kioxia Corporation, Tokyo (JP)

(21) Appl. No.: 18/973,199

(22) Filed: Dec. 9, 2024

(30) Foreign Application Priority Data
Jun. 19, 2024 (JP) 2024-098792

(51) Int. Cl. H01L 23/31; H01L 21/56; H01L 23/00

(52) U.S. Cl. CPC H01L 23/3178; H01L 21/56; H01L 24/08; H01L 24/80; H01L 2224/08145; H01L 2224/80895; H01L 2224/80896

(57) ABSTRACT

According to one embodiment, there is provided a semiconductor device including a first device structure, a second device structure and an insulating member. The first device structure has a first flat surface. The second device structure has a second flat surface bonded to the first flat surface. The insulating member is arranged between an outer end of the first device structure and an outer end of the second device structure, the insulating member including a flat portion, the flat portion internally including an extension plane of the first flat surface and the second flat surface, the flat portion extending flat along the extension plane.

### CROSS-REFERENCE TO RELATED APPLICATIONS

This application is based upon and claims the benefit of Japanese Patent Application No. 2024-098792, filed on Jun. 19, 2024; the entire contents of which are incorporated herein by reference.

### FIELD

Embodiments described herein relate generally to a semiconductor device and a method of manufacturing the semiconductor device.

### BACKGROUND

A semiconductor device is manufactured by bonding device structures of two substrates each including a device structure and a substrate portion to form a bonded body, and processing the bonded body. In manufacturing the semiconductor device, the bonded body is desirably processed appropriately.

### BRIEF DESCRIPTION OF THE DRAWINGS

FIG. 1 is a cross-sectional view illustrating a configuration of a semiconductor device according to an embodiment;

FIGS. 2A to 2E are cross-sectional views illustrating a method of manufacturing the semiconductor device according to an embodiment;

FIGS. 3A and 3B are cross-sectional views illustrating the method of manufacturing the semiconductor device according to an embodiment;

FIG. 4 is a plan view illustrating the method of manufacturing the semiconductor device according to an embodiment;

FIGS. 5A and 5B are cross-sectional views illustrating the method of manufacturing the semiconductor device according to an embodiment;

FIGS. 6A and 6B are cross-sectional views illustrating the method of manufacturing the semiconductor device according to an embodiment;

FIGS. 7A and 7B are cross-sectional views illustrating the method of manufacturing the semiconductor device according to an embodiment;

FIG. 8 is a plan view illustrating a method of manufacturing the semiconductor device according to a first modification of the embodiment;

FIG. 9 is a cross-sectional view illustrating a configuration of a semiconductor device according to a second modification of the embodiment;

FIGS. 10A and 10B are cross-sectional views illustrating a method of manufacturing the semiconductor device according to the second modification of the embodiment;

FIG. 11 is a cross-sectional view illustrating a configuration of a semiconductor device according to a third modification of the embodiment;

FIGS. 12A to 12C are cross-sectional views illustrating a method of manufacturing the semiconductor device according to the third modification of the embodiment;

FIG. 13 is a cross-sectional view illustrating a configuration of a semiconductor device according to a fourth modification of the embodiment;

FIGS. 14A and 14B are cross-sectional views illustrating a method of manufacturing the semiconductor device according to the fourth modification of the embodiment;

FIG. 15 is a cross-sectional view illustrating a configuration of a semiconductor device according to a fifth modification of the embodiment;

FIGS. 16A and 16B are cross-sectional views illustrating a method of manufacturing the semiconductor device according to the fifth modification of the embodiment;

FIGS. 17A and 17B are cross-sectional views illustrating the method of manufacturing the semiconductor device according to the fifth modification of the embodiment;

FIG. 18 is a cross-sectional view illustrating a configuration of a semiconductor device according to a sixth modification of the embodiment;

FIGS. 19A and 19B are cross-sectional views illustrating a method of manufacturing the semiconductor device according to the sixth modification of the embodiment;

FIGS. 20A and 20B are cross-sectional views illustrating the method of manufacturing the semiconductor device according to the sixth modification of the embodiment;

FIG. 21 is a cross-sectional view illustrating a configuration of a semiconductor device according to a seventh modification of the embodiment; and

FIGS. 22A and 22B are cross-sectional views illustrating a method of manufacturing the semiconductor device according to the seventh modification of the embodiment.

### DETAILED DESCRIPTION

In general, according to one embodiment, there is provided a semiconductor device including a first device structure, a second device structure and an insulating member. The first device structure has a first flat surface. The second device structure has a second flat surface bonded to the first flat surface. The insulating member is arranged between an outer end of the first device structure and an outer end of the second device structure, the insulating member including a flat portion, the flat portion internally including an extension plane of the first flat surface and the second flat surface, the flat portion extending flat along the extension plane.

Exemplary embodiments of a semiconductor device will be explained below in detail with reference to the accompanying drawings. The present invention is not limited to the following embodiments.

### Embodiments

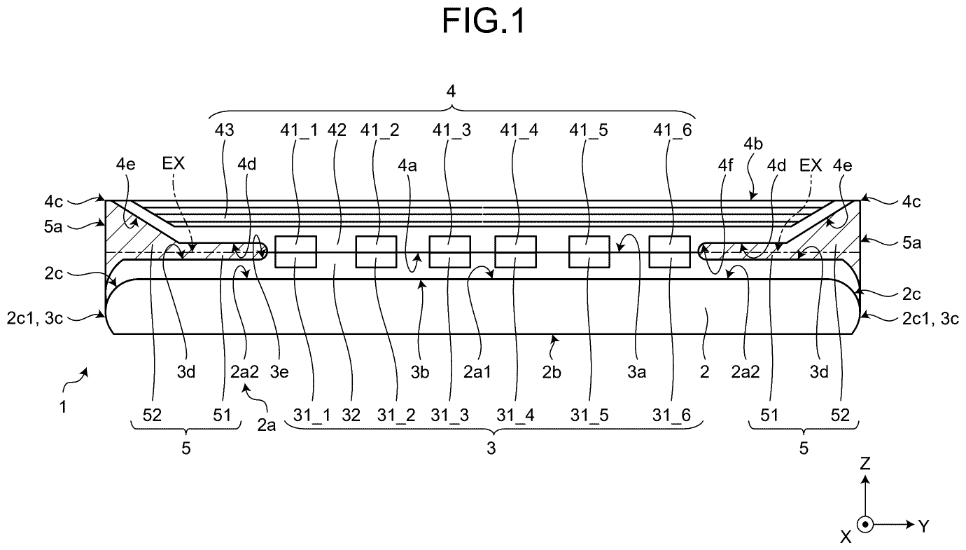

The semiconductor device according to an embodiment is manufactured by processing a bonded body of two substrates, but has a configuration suitable for appropriate processing of the bonded body in manufacturing. A semiconductor device 1 can have a configuration as illustrated in FIG. 1. FIG. 1 is a cross-sectional view illustrating a configuration of the semiconductor device 1.

The semiconductor device 1 includes a substrate portion 2, a device structure 3, a device structure 4, and an insulating member 5. Hereinafter, a direction perpendicular to a front surface 2a of the substrate portion 2 is referred to as a Z direction, and two directions orthogonal to each other in a plane perpendicular to the Z direction are referred to as an X direction and a Y direction.

The substrate portion 2 has a substantially disk shape and has a substantially circular shape in XY plane view. The substrate portion 2 can be formed of a material mainly composed of a semiconductor (e.g., silicon). The substrate portion 2 has the front surface 2a on the +Z side, a back surface 2b on the −Z side, and a curved end surface 2c on the outside of the front surface 2a and the back surface 2b in an XY direction.

The front surface 2a extends flat in the XY direction. The front surface 2a includes a main area 2a1 and a peripheral edge area 2a2. The peripheral edge area 2a2 is an annular region arranged outside the main area 2a1 in the XY direction to surround the main area 2a1 in XY plane view.

The back surface 2b extends flat in the XY direction. The back surface 2b may be planarized, and may form an obtuse angle with the curved end surface 2c in the vicinity of an end portion thereof in a cross-sectional view along a Z axis (e.g., YZ cross-sectional view).

The curved end surface 2c includes an outer end 2c1 of the substrate portion 2. The curved end surface 2c extends from an end portion of the front surface 2a (an end portion of the peripheral edge area 2a2) while curving outward in a −Z direction and the XY direction, in the YZ cross-sectional view, reaching the outer end 2c1 of the substrate portion 2, then extending to an end portion of the back surface 2b while curving inward in the −Z direction and the XY direction.

The device structure 3 is arranged on the front surface 2a. The device structure 3 may be arranged up to the curved end surface 2c. The device structure 3 has an outer end 3c, which may be positioned near the outer end 2c1 of the substrate portion 2. The device structure 3 has a main portion that is arranged in the main area 2a1. The device structure 3 may function as a control circuit for controlling the device structure 4. The device structure 3 may include structures of multiple CMOS devices that function as the control circuit.

The device structure 3 has a flat surface 3a and a flat surface 3d on the +Z side, and a flat surface 3b on the −Z side. The flat surface 3a covers a flat surface 4a of the device structure 4 in the XY direction. The flat surface 3d is arranged outside the flat surface 3a in the XY direction and extends annularly in XY plane view to surround the flat surface 3a. A Z height of the flat surface 3d from the front surface 2a is smaller than a Z height of the flat surface 3a from the front surface 2a. At a boundary between the flat surface 3a and the flat surface 3d, a stepped surface 3e corresponding to the difference therebetween in the Z height is arranged. The flat surface 3b covers the front surface 2a of the substrate portion 2 in the XY direction.

The device structure 3 includes multiple electrodes 31_1 to 31_6, an interlayer dielectric film 32, multiple conductive patterns, and the like. The electrodes 31_1 to 31_6 are arranged in the vicinity of the flat surface 3a. The electrodes 31_1 to 31_6 have surfaces on the +Z side that are exposed from the flat surface 3a. The surfaces of the electrodes 31_1 to 31_6 on the +Z side and the flat surface 3a form a continuous surface. Although not illustrated for simplicity, the multiple conductive patterns enable to function as lines extending across the interlayer dielectric film 32, or the multiple conductive patterns enable to function as electrodes for a CMOS device by covering the front surface 2a of the substrate portion 2 or by being arranged in the vicinity of the front surface 2a in the substrate portion 2.

The device structure 4 is arranged on the flat surface 3a. An XY position of an outer end 4c of the device structure 4 may be near an XY position of the outer end 2c1 of the substrate portion 2. The device structure 4 has a main portion that is arranged on the flat surface 3a. The device structure 4 may function as a memory cell array. The device structure 4 may include a structure having a three-dimensional arrangement of multiple memory cells.

The device structure 4 has the flat surface 4a, a flat surface 4d, and an inclined side surface 4e on the −Z side, and a flat surface 4b on the +Z side. The flat surface 4a covers the flat surface 3a of the device structure 3 in the XY direction. The flat surface 4d is arranged outside the flat surface 4a in the XY direction and extends annularly in XY plane view to surround the flat surface 4a. A Z height of the flat surface 4d from the front surface 2a is larger than a Z height of the flat surface 4a from the front surface 2a. At a boundary between the flat surface 4a and the flat surface 4d, a stepped surface 4f corresponding to the difference therebetween in the Z height is arranged. The flat surface 4b is exposed on the +Z side.

The device structure 4 includes multiple electrodes 41_1 to 41_6, an interlayer dielectric film 42, a stacked body 43, multiple columnar bodies (not illustrated), and the like. The electrodes 41_1 to 41_6 are arranged in the vicinity of the flat surface 4a. The electrodes 41_1 to 41_6 have surface on the −Z side that are exposed from the flat surface 4a. The surfaces of the electrodes 41_1 to 41_6 on the −Z side and the flat surface 4a form a continuous surface.

The electrodes 41_1 to 41_6 correspond to the electrodes 31_1 to 31_6. Each of the electrodes 41 is bonded to a corresponding electrode 31, for electrical connection.

In the stacked body 43, conductive films and insulating films are alternately stacked multiple times in the Z direction. Although not illustrated for simplicity, the multiple columnar bodies may be two-dimensionally arranged in the XY direction and each of the multiple columnar bodies may penetrate the stacked body 43 in the Z direction. Each columnar body can be formed of a material mainly composed of a semiconductor. Multiple positions where the multiple columnar bodies and the multiple conductive films intersect can function as multiple memory cells.

The insulating member 5 is arranged between the outer end 3c of the device structure 3 and the outer end 4c of the device structure 4 in the Z direction. The insulating member 5 is arranged outside the flat surface 3a and the flat surface 4a in the XY direction. The insulating member 5 is formed of an insulator. The insulator may include at least one of a semiconductor oxide, a semiconductor nitride, and a semiconductor oxynitride. The insulating member 5 may be formed of an insulator having a different composition from the interlayer dielectric film 32 and the interlayer dielectric film 42, or may be formed of an insulator having the same composition as the interlayer dielectric film 32 and the interlayer dielectric film 42 but having a different film density therefrom.

The insulating member 5 includes a flat portion 51 and an outer peripheral portion 52. The flat portion 51 is arranged between the flat surface 3a and the flat surface 4a, and the outer peripheral portion 52. The flat portion 51 internally includes an extension plane EX extending from between the flat surface 3a and the flat surface 4a. The flat portion 51 extends flat along the extension plane EX.

The flat surface 3a and the flat surface 4a may each have a substantially circular shape in XY plane view. The flat portion 51 may extend annularly on the outside of the flat surface 3a and the flat surface 4a in the XY direction, in XY plane view, to surround the flat surface 3a and the flat surface 4a substantially circularly. The flat portion 51 has a Z thickness that is uniform in a radial direction (e.g., in the Y direction in a YZ cross-section of FIG. 1). The flat portion 51 has a Z height from a main surface 2a of the substrate portion 2 that is uniform in the radial direction.

The outer peripheral portion 52 is arranged outside the flat portion 51 in the XY direction. The outer peripheral portion 52 may have a Z thickness, which gradually increases from the flat portion 51 toward the outside in the XY direction. The outer peripheral portion 52 may have a substantially triangular shape in a cross-sectional view along the Z axis.

The outer peripheral portion 52 has an outer side surface 5a, which may extend in the Z direction from the outer end 4c of the device structure 4 to reach the outer end 3c of the device structure 3. In FIG. 1, for the sake of simplicity, the outer side surface 5a is illustrated as a surface extending flat in the Z direction. The outer side surface 5a may have a curved surface shape bulging outward in the XY direction. The outer side surface 5a may extend from the outer end 4c of the device structure 4 to a predetermined Z position while curving outward in the −Z direction and the XY direction, extending from the predetermined Z position to the outer end 3c of the device structure 3 while curving inward in the −Z direction and the XY direction.

The insulating member 5 is in contact with the vicinity of the outer end of the device structure 3 from the +Z side, and is in contact with the vicinity of the outer end of the device structure 4 from the −Z side. The insulating member 5 is in contact with the flat surface 3d of the device structure 3 and the flat surface 4d and the inclined side surface 4e of the device structure 4, and supports both the device structure 3 and the device structure 4.

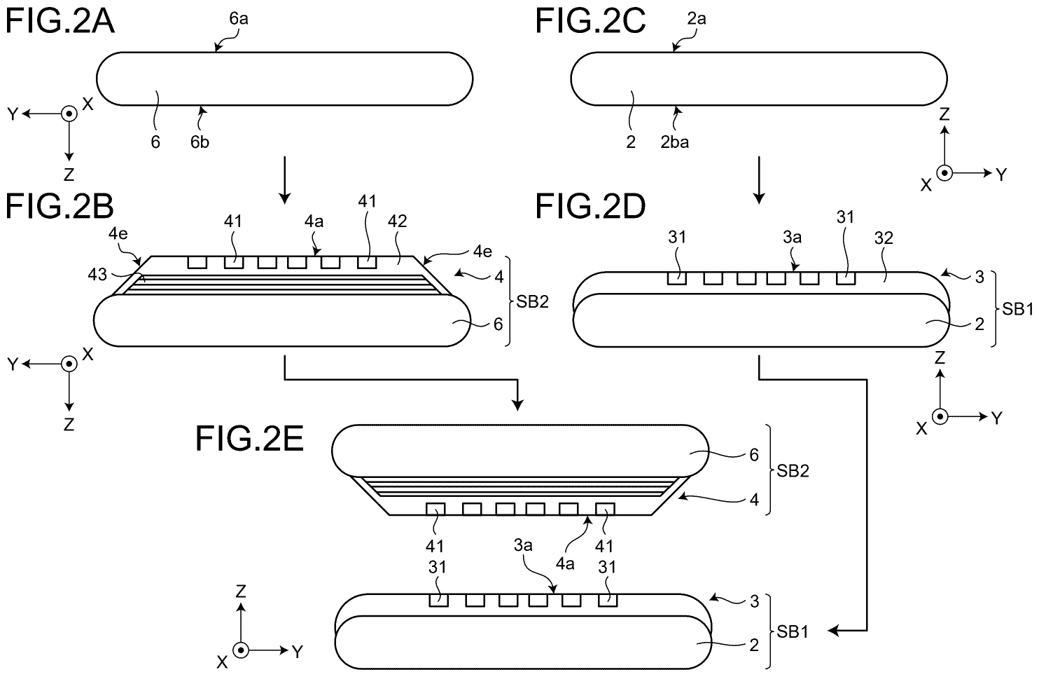

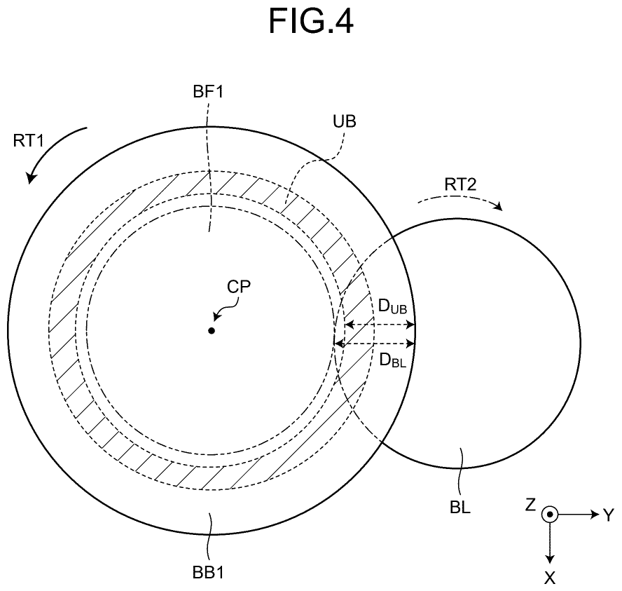

Next, a method of manufacturing the semiconductor device 1 will be described with reference to FIG. 1 and FIGS. 2A to 7B. FIGS. 2A to 2E, FIGS. 3A and 3B, FIGS. 5A and 5B, FIGS. 6A and 6B, and FIGS. 7A and 7B are YZ cross-sectional views each illustrating the method of manufacturing the semiconductor device 1. FIG. 4 is an XY plan view illustrating the method of manufacturing the semiconductor device 1. FIG. 1 is a diagram illustrating the configuration of the semiconductor device 1, but will be also used as a diagram illustrating the method of manufacturing the semiconductor device 1.

In the method of manufacturing the semiconductor device 1, the steps of FIGS. 2A to 2B and the steps of FIGS. 2C to 2D are performed in parallel. After the steps of FIGS. 2A to 2B and the steps of FIGS. 2C to 2D are both completed, the steps of FIGS. 2E to 6B are performed. Each step is actually performed using a substrate on which multiple chip areas is mounted, but for the sake of simplicity, each cross-sectional view illustrates a cross-section of a substrate on which one chip area is mounted.

In the step of FIG. 2A, a substrate portion 6 is prepared. The substrate portion 6 has a substantially disk shape and has a substantially circular shape in XY plane view. The substrate portion 6 has a main surface 6a on the −Z side and a main surface 6b on the +Z side. The substrate portion 6 can be formed of a material mainly composed of a semiconductor (e.g., silicon).

In the step of FIG. 2B, the device structure 4 is formed on the main surface 6a of the substrate portion 6. The device structure 4 may include a memory cell array structure in which multiple memory cells are three-dimensionally arranged.

After an insulating film is deposited on a front surface 6a of the substrate portion 6 and then a conductive film is deposited thereon, insulating layers and sacrificial layers are alternately deposited multiple times to form a stacked body 43a. The insulating layers can be formed of an insulator such as a silicon oxide. The sacrificial layers can be formed of an insulator (e.g., silicon nitride or the like) that enables to secure etching selectivity to the insulating layer. Each of the insulating layers and each of the sacrificial layers can be deposited with a substantially similar film thickness.

A resist pattern in which a formation position of a separation film is opened in a line shape extending in the Y direction is formed on an uppermost insulating layer on the −Z side. Anisotropic etching such as a reactive ion etching (RIE) method is performed using the resist pattern as a mask to form a groove penetrating the stacked body 43a in a YZ direction. Then, the separation film is embedded in the groove. The separation film can be formed of a material mainly composed of an insulator (e.g., silicon oxide). The separation film extends in the YZ direction in a stacked body 43a to divide the stacked body 43a into multiple stacked bodies 43b arranged in the X direction. In each of the stacked bodies 43b, the insulating layers and the sacrificial layers are alternately stacked multiple times.

A resist pattern in which formation positions of memory holes are opened is formed, on the −Z side of a lowermost insulating layer of each stacked body 43b on the +Z side, and the −Z side of the separation film. The resist pattern is used as a mask to perform anisotropic etching such as RIE to form the memory holes penetrating the stacked body 43b and reaching the conductive film.

A block insulating film, a charge storage film, and a tunnel insulating film are sequentially deposited on a side surface and a bottom surface of each of the memory holes. The block insulating film can be formed of an insulator such as a silicon oxide. The charge storage film can be formed of an insulator such as a silicon nitride. The tunnel insulating film can be formed of an insulator such as a silicon oxide. In each of the block insulating film, the charge storage film, and the tunnel insulating film, a portion at the bottom surface of the memory hole is selectively removed.

A semiconductor film is deposited on the side surface and the bottom surface of the memory hole. The semiconductor film can be formed of a material mainly composed of a semiconductor (e.g., polysilicon). Then, a core member is embedded into the memory hole. The core member can be formed of an insulator such as a silicon oxide. As a result, the columnar body penetrating the stacked body 43b in the Z direction is formed.

The sacrificial layer of the stacked body 43b is removed. An insulating film is formed on an exposed surface of a void formed by the removal. The insulating film can be formed of an insulator such as an aluminum oxide. A conductive layer is further embedded into the void. The conductive layer can be formed of a material mainly composed of a conductive material (e.g., a metal such as tungsten). As a result, the stacked body 43 in which the conductive layers and the insulating layers are alternately stacked repeatedly is formed.

As a result, the memory cell array structure in which the multiple memory cells is three-dimensionally arranged is formed. In the memory cell array structure, the multiple memory cells are formed at multiple positions of the stacked body 43 where multiple the conductive layers and multiple the semiconductor films of columnar bodies intersect. Note that the conductive film arranged on the +Z side of the stacked body 43 functions as a source region in the memory cell array structure. The lowermost conductive layer on the +Z side of the multiple conductive layers functions as a source side selection gate line. The uppermost conductive layer on the −Z side of the multiple conductive layers functions as a drain side selection gate line. The remaining conductive layers of the multiple conductive layers each function as a word line.

Furthermore, the interlayer dielectric film 42 is further deposited to form a predetermined wiring structure (not illustrated), and a surface of the interlayer dielectric film 42 on the −Z side is planarized to form the flat surface 4a. Holes and/or the grooves are formed at positions in the flat surface 4a corresponding to the predetermined wiring structure. A conductive material (e.g., a material mainly composed of copper or the like) is embedded into each of the holes and/or the grooves to form each electrode 41.

Therefore, the device structure 4 having the memory cell array structure including the electrodes 41, the interlayer dielectric film 42, and the stacked body 43 is formed. A configuration including the substrate portion 6 and the device structure 4 will be referred to as a substrate SB2. The device structure 4 may have the inclined side surface 4e on the outside in the XY direction.

In the step of FIG. 2C, the substrate portion 2 is prepared. The substrate portion 2 has a substantially disk shape and has a substantially circular shape in XY plane view. The substrate portion 2 has the main surface 2a on the +Z side and a main surface 2ba on the −Z side. The substrate portion 2 can be formed of a material mainly composed of a semiconductor (e.g., silicon).

In the step of FIG. 2D, impurities are introduced into a partial area of the main surface 2a of the substrate portion 2, or a conductive film is deposited on the main surface 2a for patterning to form electrodes of a transistor. The conductive film can be formed of a semiconductor (e.g., polysilicon) to which conductivity is imparted. The interlayer dielectric film 32 is deposited to cover the transistor. The interlayer dielectric film 32 can be formed of a silicon oxide. Thereafter, holes for exposing the electrodes of the transistor are formed in the interlayer dielectric film 32, and a conductive material (e.g., tungsten or the like) is embedded into the holes to form a wiring structure. Therefore, the device structure 3 including a circuit structure including the transistor is formed. In the step of FIG. 2D, the circuit structure is not illustrated, for the sake of simplicity.

Furthermore, the interlayer dielectric film 32 is deposited to form a predetermined wiring structure (not illustrated), and a surface of the interlayer dielectric film 32 on the −Z side is planarized to form the flat surface 3a. Holes and/or grooves are formed at positions in the flat surface 3a corresponding to the predetermined wiring structure. A conductive material (e.g., a material mainly composed of copper or the like) is embedded into each of the holes and/or the grooves to form each electrode 31. Therefore, the substrate portion 2 including the multiple chip areas is obtained. Each of the chip areas includes the circuit structure and is also referred to as a circuit chip. In each chip area, the flat surface 3a of the interlayer dielectric film 32 on the +Z side is exposed, and the multiple electrodes 31 is arranged in the flat surface 3a.

Therefore, the device structure 3 having the electrodes 31, the interlayer dielectric film 32, and the circuit structure is formed. A configuration including the substrate portion 2 and the device structure 3 will be referred to as a substrate SB1.

In the step of FIG. 2E, the flat surface 3a of the substrate SB1 and the flat surface 4a of the substrate SB2 can be activated by plasma irradiation or the like. The substrate SB1 and the substrate SB2 are arranged so that the flat surface 3a and the flat surface 4a face each other. An XY position of the substrate SB1 and an XY position of the substrate SB2 are aligned so that XY positions of the electrodes 31 in the flat surface 3a correspond to XY positions of the electrodes 41 in the flat surface 4a.

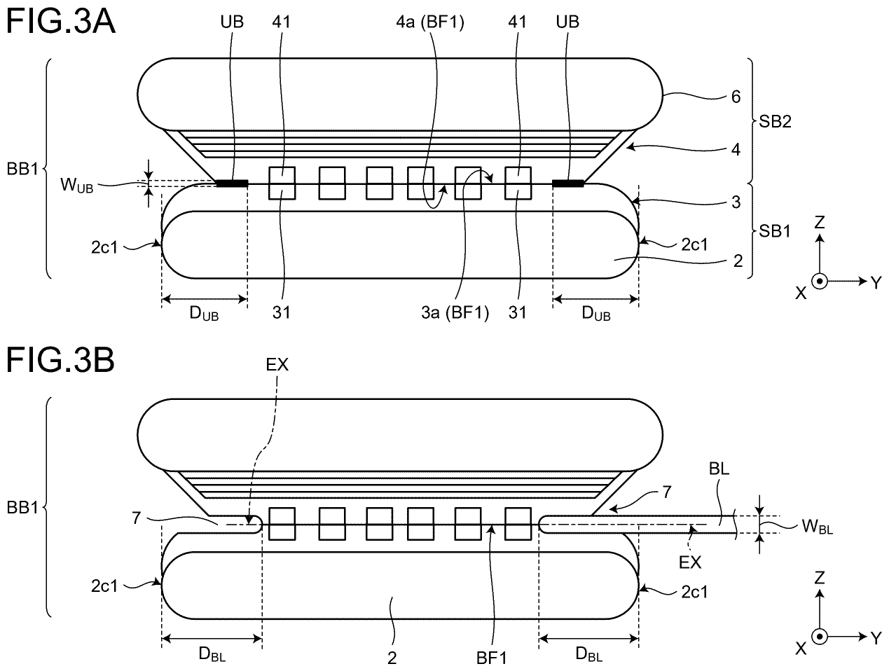

In the step of FIG. 3A, the substrate SB1 and the substrate SB2 are brought closer to each other in the Z direction to bond the flat surface 3a and the flat surface 4a. At this time, the substrate SB1 and the substrate SB2 may be heated/pressurized.

Therefore, the electrodes 31 and the electrodes 41 are allowed to be readily aligned to bond the substrate SB1 and the substrate SB2, and a bonded body BB1 in which the substrate SB1 and the substrate SB2 are bonded on a bonded surface BF1 is formed. On the bonded surface BF1, the flat surface 3a and the flat surface 4a can be bonded by direct bonding, and the electrodes 31 and the electrodes 41 can be bonded by direct bonding. At this time, an unbonded area can be formed in a region indicated by a black thick line on an outer peripheral side of the bonded surface BF1.

The unbonded area is an area where bonding is not appropriately performed, and in which mechanical damage such as a crack is included in the vicinity of a surface of the substrate SB1 on the +Z side or a surface of the substrate SB2 on the −Z side or a void is formed due to separation between the surface of the substrate SB1 on the +Z side and the surface of the substrate SB2 on the −Z side in the Z direction. When the unbonded area is left as is, a portion in the vicinity of the unbonded area that is weak in strength is easily chipped by subsequent polishing or the like, scattered as scrap pieces in a polisher, and may cause mechanical damage on a polished surface. A portion in the vicinity of the unbonded area, which is weak in strength, may enter an area where bonding has been appropriately performed, due to enlargement of the void by subsequent heat treatment or the like. This may make it difficult to appropriately perform subsequent steps.

Therefore, the unbonded area is measured for the bonded body BB1. The measurement of the unbonded area may be performed by a scanning acoustic tomograph (SAT) (FS100II manufactured by Hitachi Construction Machinery FineTech Co Ltd). In the measurement of the unbonded area, a SAT image of the bonded body BB1 is acquired, and the SAT image is analyzed to measure a depth of the unbonded area in the XY direction. The depth of the unbonded area in the XY direction may be measured as an XY direction distance D_{UB} from the outer end 2c1 of the substrate portion 2 to an inner end of the unbonded area. A depth D_{UB} of the unbonded area in the XY direction is measured at multiple positions in a circumferential direction. In the example of FIG. 3A, the depth D_{UB} of the unbonded area UB in the XY direction, on the +Y side is measured, and the depth D_{UB} of the unbonded area UB in the XY direction, on the −Y side is measured. The depth D_{UB} of the unbonded area in the XY direction may be obtained by selecting a maximum value from measured values at the multiple positions.

Note that a Z thickness W_{UB} of the unbonded area may be experimentally determined in advance, as a Z thickness of an unbonded area formed on average when multiple substrates is bonded.

In the step of FIG. 3B, according to a result of the measurement of the unbonded area, a groove 7 is formed inward from the outside along the bonded surface BF1 of the bonded body BB1 to remove the unbonded area. As illustrated in FIGS. 3B and 4, the groove 7 may be formed by cutting with a blade BL.

A formation depth of the groove 7 may be determined as an XY direction distance D_{BL} from the outer end 2c1 of the substrate portion 2 to the inner end of the unbonded area. A formation depth Der of the groove 7 can be determined according to the depth D_{UB} of the unbonded area in the XY direction measured in the step of FIG. 3A. As illustrated in FIG. 3B, a depth D_{BL} of the groove 7 in the XY direction may be larger than the depth D_{UB} of the unbonded area in the XY direction, and may have a value D_{BL} (=D_{UB}+ΔD) obtained by adding a processing margin ΔD of the blade BL in the XY direction to the depth D_{UB} of the unbonded area in the XY direction.

The groove 7 has a formation thickness that is substantially equal to a Z thickness W_{BL} of the blade BL. As illustrated in FIG. 3B, a formation thickness W_{BL} of the groove 7 may be larger than the Z thickness W_{UB} of the unbonded area, and may have a value W_{BL} (=W_{UB}+ΔW) obtained by adding a processing margin ΔW of the blade BL in the Z direction to the Z thickness W_{UB} of the unbonded area.

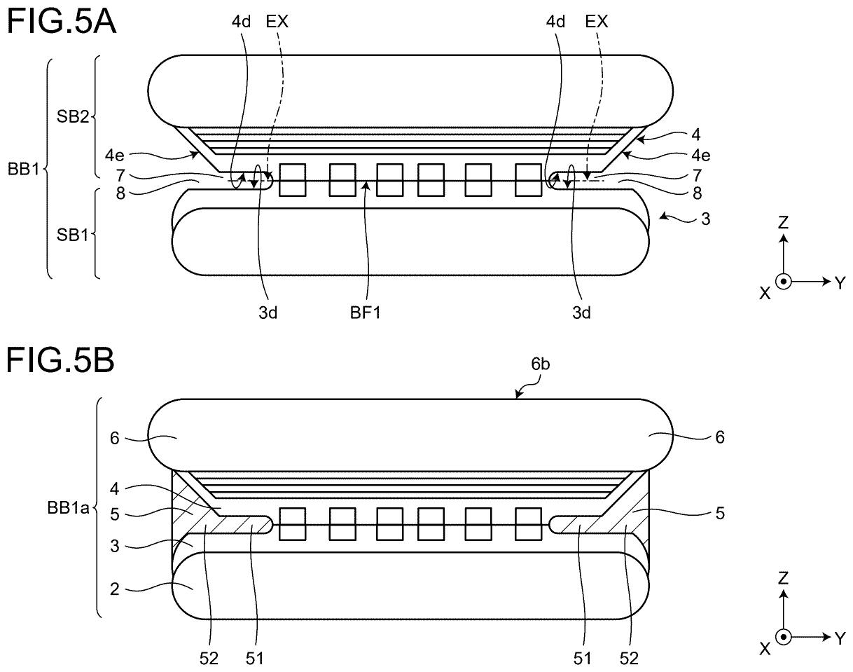

A cutting device (not illustrated) rotates the bonded body BB1 around the Z axis in a direction RT1 as indicated by a solid arrow in FIG. 4, and rotates the blade BL around the Z axis in an opposite direction RT2 indicated by a one-dot chain line arrow in FIG. 4. In FIG. 4, the unbonded area UB is obliquely hatched. The XY direction depth of the unbonded area UB is represented by D_{UB}. In this state, an area in the vicinity of the bonded surface BF1 including the unbonded area UB is cut, while the blade BL is gradually brought closer to a center CP of the bonded body BB1, from outside the bonded surface BF1 in the XY direction. The cutting is performed until the tip of the blade BL reaches an XY direction depth Der as illustrated in FIG. 4. Therefore, as illustrated in FIGS. 4 and 5A, the unbonded area UB is removed, and the groove 7 internally including the extension plane EX of the bonded surface BF1 is formed. An opening 8 having a substantially triangular shape in a cross-sectional view along the Z axis is formed between the inclined side surface 4e of the device structure 4 and the device structure 3, on the outside of the groove 7 in the XY direction.

In the step of FIG. 5B, an insulating material is embedded into the groove 7 and the opening 8 to form the insulating member 5. The embedding of the insulating material may be performed by a CVD method or the like using a processing gas corresponding to the insulating material, or may be performed by a coating method or the like using a solution containing the insulating material. For the insulating material, a substance having relatively high viscosity may be used. For the insulating material, an organic adhesive containing a filler or a silica-based inorganic adhesive containing a filler may be used. The insulating material may be a urethane-based resin, an epoxy resin, or the like. The filler is an aggregate to reduce thermal shrinkage of an embedded material to be filled, and includes, for example, silica particles used as an abrasive.

The insulating material is embedded into the groove 7 to form the flat portion 51 flat in the XY direction. The insulating material is embedded into the opening 8 to form the outer peripheral portion 52 having a substantially triangular shape in a cross-sectional view along the Z axis. The insulating member 5 including the flat portion 51 and the outer peripheral portion 52 is formed to make contact with the flat surface 3d of the device structure 3 and the flat surface 4d and the inclined side surface 4e of the device structure 4. This configuration forms a bonded body BB1a that is configured to support both the device structure 3 and the device structure 4 by the insulating member 5, on the outside of the bonded surface BF1 in the XY direction.

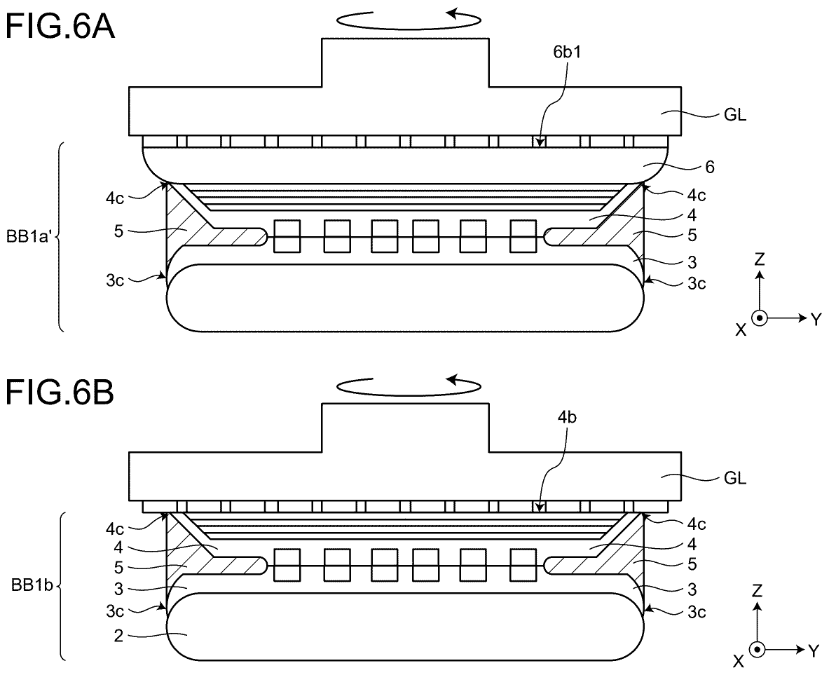

In the step illustrated in FIG. 6A, a grinder GL of the polisher is pressed against a back surface 6b of the substrate portion 6, and the grinder GL rotates about an axis perpendicular to a contact surface. Therefore, the substrate portion 6 is thinned. At this time, in a bonded body BB1a′, the insulating member 5 supports both the device structure 3 and the device structure 4. Therefore, a portion in the vicinity of the outer end 3c of the device structure 3 and/or a portion in the vicinity of the outer end 4c of the device structure 4 is inhibited from being chipped, suppressing generation of the scrap pieces.

In the process illustrated in FIG. 6B, the grinder GL of the polisher is continuously pressed against a back surface 6b1 of the substrate portion 6, and the grinder GL rotates about the axis perpendicular to the contact surface. Therefore, the substrate portion 6 is polished until the flat surface 4b of the device structure 4 is exposed. As a result, the substrate portion 6 is removed off. At this time, in a bonded body BB1b, the insulating member 5 continuously supports both the device structure 3 and the device structure 4. Therefore, a portion in the vicinity of the outer end 3c of the device structure 3 and/or a portion in the vicinity of the outer end 4c of the device structure 4 is inhibited from being chipped, suppressing generation of the scrap pieces. In addition, presence of the insulating member 5 makes it possible to readily maintain the flatness of the flat surface 4b.

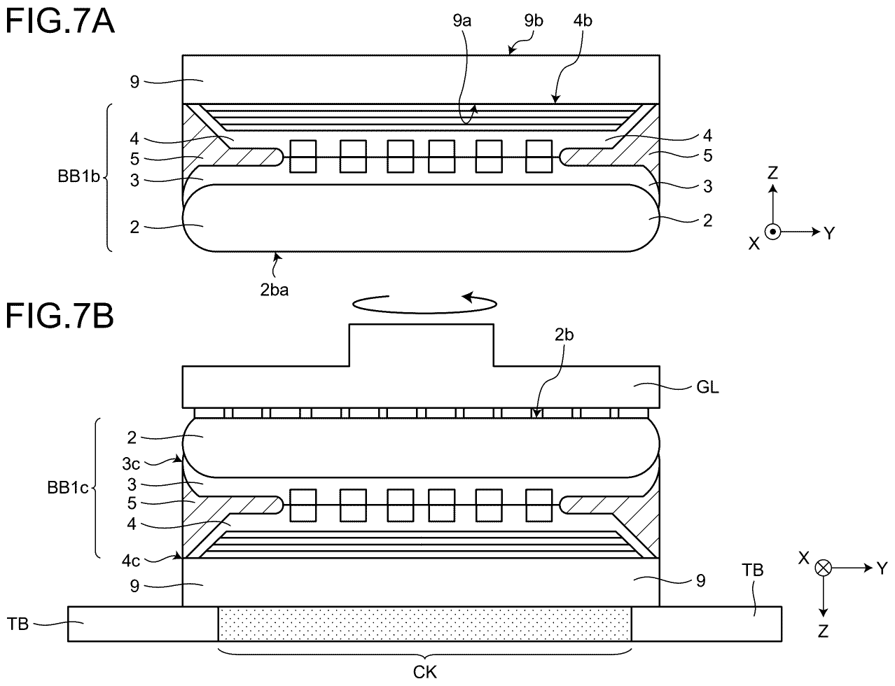

In the step illustrated in FIG. 7A, a protective member 9 is applied to the flat surface 4b of the device structure 4 on the +Z side. The protective member 9 may be a protective tape in which an adhesive is applied to a surface 9a on the −Z side of a base material. In other words, the protective member 9 is applied to the +Z side of the bonded body BB1b. At this time, in the bonded body BB1b, the presence of the insulating member 5 facilitates maintaining the flatness of the flat surface 4b, and therefore, an inexpensive member (e.g., the protective member 9 having a relatively small thickness) can be adopted as the protective member 9, reducing the manufacturing cost. In addition, the presence of the insulating member 5 facilitates maintaining the flatness of the flat surface 4b, and therefore, the flatness of the surface 9a of the protective member 9 on the +Z side can be readily secured.

In the step illustrated in FIG. 7B, the bonded body BB1b to which the protective member 9 is applied is placed on a table TB having a chuck mechanism CK in a direction in which the surface 9a of the protective member 9 on the +Z side makes contact with the table TB. The chuck mechanism CK may be a vacuum chuck mechanism including multiple holes penetrating the table TB in the Z direction and communicable with an exhaust device (not illustrated). The chuck mechanism CK sucks the protective member 9 and the bonded body BB1b to the table TB. At this time, in the bonded body BB1b, the presence of the insulating member 5 facilitates maintaining the flatness of the flat surface 4b, the flatness of the surface 9a of the protective member 9 on the +Z side can be readily secured, and therefore, the chuck mechanism CK is allowed to readily suck the protective member 9 and the bonded body BB1b to the table TB.

In this state, the grinder GL of the polisher is pressed against a back surface 2ba of the substrate portion 2, and the grinder GL rotates about the axis perpendicular to the contact surface. Therefore, the substrate portion 2 is thinned and the back surface 2b of the substrate portion 2 is polished. At this time, in a bonded body BB1c, the insulating member 5 supports both the device structure 3 and the device structure 4. Therefore, a portion in the vicinity of the outer end 3c of the device structure 3 and/or a portion in the vicinity of the outer end 4c of the device structure 4 is inhibited from being chipped, suppressing generation of the scrap pieces.

Thereafter, the chucking by the chuck mechanism CK is released, the protective member 9 and the bonded body BB1b are removed from the table TB, and the protective member 9 is removed off. Thus, the semiconductor device 1 as illustrated in FIG. 1 is manufactured.

As described above, in the embodiment, in the semiconductor device 1 manufactured by processing the bonded body of the two substrates, the insulating member 5 includes the flat portion 51 that is arranged on the outside of the bonded surface BF1 (the flat surfaces 3a and 4a of the device structures 3 and 4) in the XY direction, that is internally includes the extension plane EX of the bonded surface BF1, and that extends flat along the extension plane EX. The flat portion 51 is formed by embedding the insulating material into the groove formed by removing the unbonded area formed by bonding the two substrates, having a structure suitably configured to avoid failure caused by leaving the unbonded area as is. The flat portion 51 has a structure configured to support the device structures 3 and 4 in a bonded body BB upon manufacturing and appropriately support subsequent polishing and heat treatment of the bonded body BB. In other words, this structure makes it possible to provide the semiconductor device 1 suitable for appropriate processing of the bonded body BB upon manufacturing.

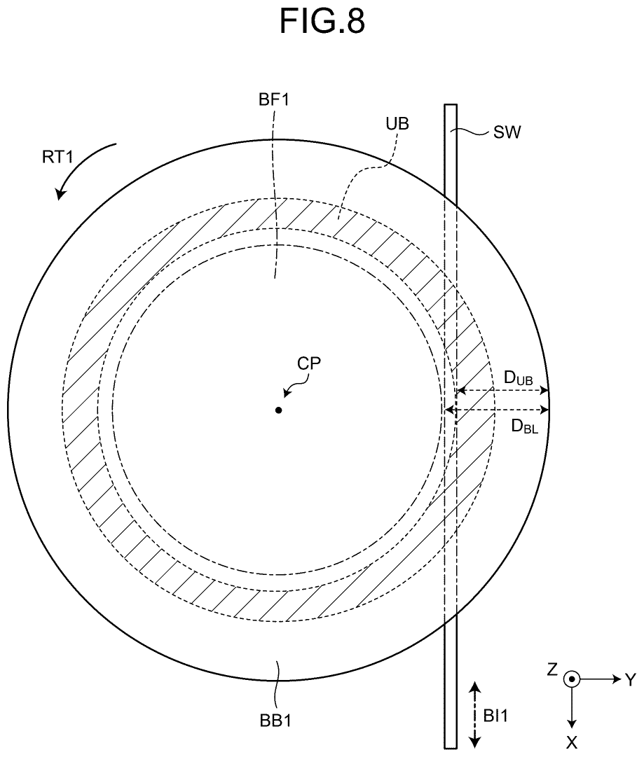

Note that in a first modification of the embodiment, the cutting of the unbonded area in the step illustrated in FIG. 3B may be performed using a wire saw SW illustrated in FIG. 8 instead of the blade BL (see FIG. 4). FIG. 8 is a plan view illustrating a method of manufacturing the semiconductor device according to the first modification of the embodiment.

The cutting device (not illustrated) rotates the bonded body BB1 around the Z axis in the direction RT1 indicated by a solid arrow in FIG. 8, and vibrates the wire saw SW in a direction BI1 indicated by a one-dot chain line arrow in FIG. 8. In FIG. 8, the unbonded area UB is obliquely hatched. The XY direction depth of the unbonded area UB is represented by D_{UB}. In this state, an area in the vicinity of the bonded surface BF1 including the unbonded area UB is cut, while the wire saw SW is gradually brought closer to the center CP of the bonded body BB1, from outside the bonded surface BF1 in the XY direction. The cutting is performed until the tip of the wire saw SW reaches the XY direction depth Der as illustrated in FIG. 8.

The formation depth of the groove 7 may be determined as the XY direction distance D_{BL} from the outer end 2c1 of the substrate portion 2 to the inner end of the unbonded area, and the formation thickness of the groove 7 is substantially equal to a Z thickness of the wire saw SW, as in the embodiment.

The cutting as described above makes it also possible to remove the unbonded area UB and form the groove 7 internally including the extension plane EX of the bonded surface BF1, as illustrated in FIGS. 8 and 5A.

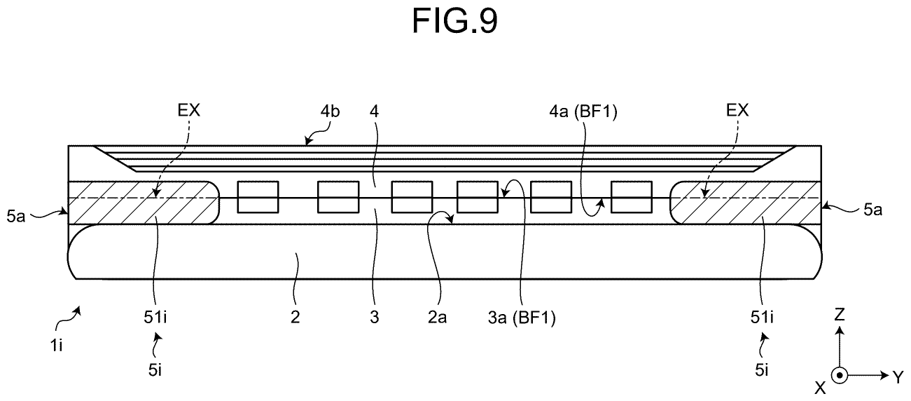

Alternatively, in the second modification of the embodiment, as illustrated in FIG. 9, an insulating member 5i may be configured to have a thickness corresponding to that of the device structure 3, in a semiconductor device 1i. FIG. 9 is a cross-sectional view illustrating a configuration of the semiconductor device 1i according to the second modification of the embodiment.

The insulating member 5i includes a flat portion 51i instead of the flat portion 51 (see FIG. 1) and does not include the outer peripheral portion 52 (see FIG. 1). The flat portion 51i extends from an end of the bonded surface BF1 (i.e., the flat surfaces 3a and 4a) to the outer side surface 5a of the insulating member 5i along the extension plane EX. The flat portion 51i has a Z thickness that corresponds to a Z thickness of the device structure 3. The Z thickness of the flat portion 51i may be larger than the Z thickness of the device structure 3. The flat portion 51i may be in contact with the front surface 2a of the substrate portion 2. The flat portion 51i is similar to the flat portion 51 of the embodiment in that the Z thickness is uniform in the radial direction.

The device structure 4 may have a side surface 4e1 flat in the Z direction, instead of the inclined side surface 4e (see FIG. 1).

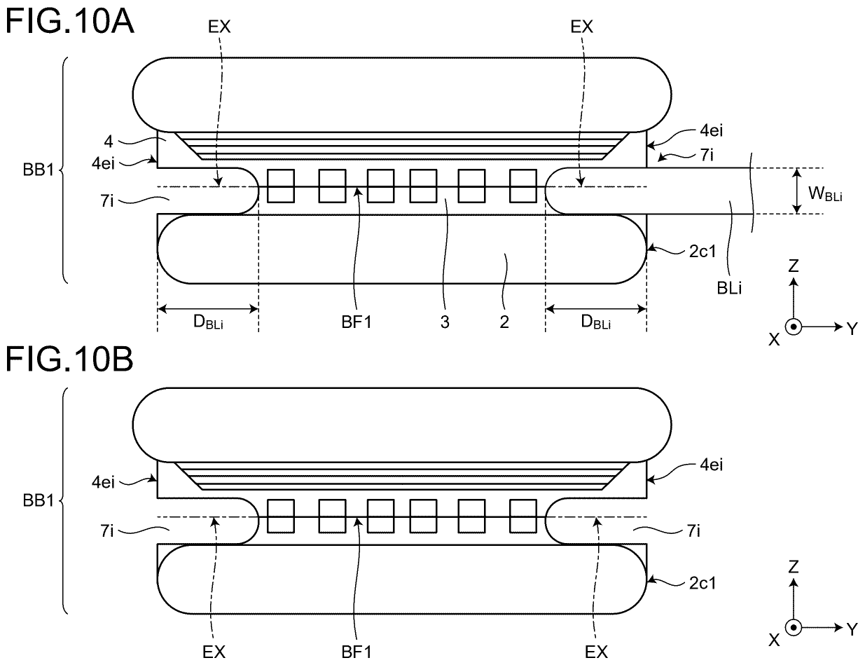

Furthermore, in a method of manufacturing the semiconductor device 1i, the step of FIG. 10A may be performed instead of the step of FIG. 3B.

In the step of FIG. 10A, according to a result of the measurement of the unbonded area (see FIG. 3A), a groove 7i is formed inward from the outside along the bonded surface BF1 of the bonded body BB1 to remove the unbonded area. As illustrated in FIG. 3B, the groove 7i may be formed by cutting with a blade BLi.

A formation depth of the groove 7i may be determined as an XY direction distance D_{BLi} from the outer end 2c1 of the substrate portion 2 to the inner end of the unbonded area. A formation depth D_{BLi} of the groove 7i can be determined according to the depth D_{UB} of the unbonded area in the XY direction measured in the step of FIG. 3A. As illustrated in FIG. 10A, a depth D_{BLi} of the groove 7i in the XY direction may be larger than the depth D_{UB} of the unbonded area in the XY direction, and may have a value D_{BLi} (=D_{UB}+ΔD) obtained by adding the processing margin ΔD of the blade BLi in the XY direction to the depth D_{UB} of the unbonded area in the XY direction.

The groove 7i has a formation thickness that is substantially equal to a Z thickness WeLi of the blade BLi. As illustrated in FIG. 10A, a formation thickness W_{BLi} of the groove 7i may be larger than the Z thickness W_{UB} of the unbonded area, and may have a value W_{BLi} (=W_{UB}+W3+ΔW) obtained by adding a Z thickness W3 of the device structure 3 and the processing margin ΔW of the blade BL in the Z direction to the Z thickness W_{UB} of the unbonded area.

The cutting device (not illustrated) rotates the bonded body BB1 around the Z axis in the direction RT1 (see FIG. 4), and rotates the blade BLi around the Z axis in the opposite direction RT2 (see FIG. 4). In this state, an area in the vicinity of the bonded surface BF1 including the unbonded area UB is cut, while the blade BL is gradually brought closer to a center CP of the bonded body BB1, from outside the bonded surface BF1 in the XY direction. The cutting is performed until the tip of the blade BLi reaches an XY direction depth D_{BLi}. Therefore, as illustrated in FIG. 10B, the unbonded area UB is removed, and the groove 7i internally including the extension plane EX of the bonded surface BF1 is formed.

In the semiconductor device 1i also configured in this manner, the flat portion 51i of the insulating member 5i is formed by embedding the insulating material into the groove 7i formed by removing the unbonded area formed by bonding the two substrates, having a structure suitably configured to avoid failure caused by leaving the unbonded area as is. The flat portion 51i has a structure configured to support the device structures 3 and 4 in the bonded body BB upon manufacturing and appropriately support subsequent polishing and heat treatment of the bonded body BB. In other words, this structure also makes it possible to provide the semiconductor device 1i suitable for appropriate processing of the bonded body BB upon manufacturing.

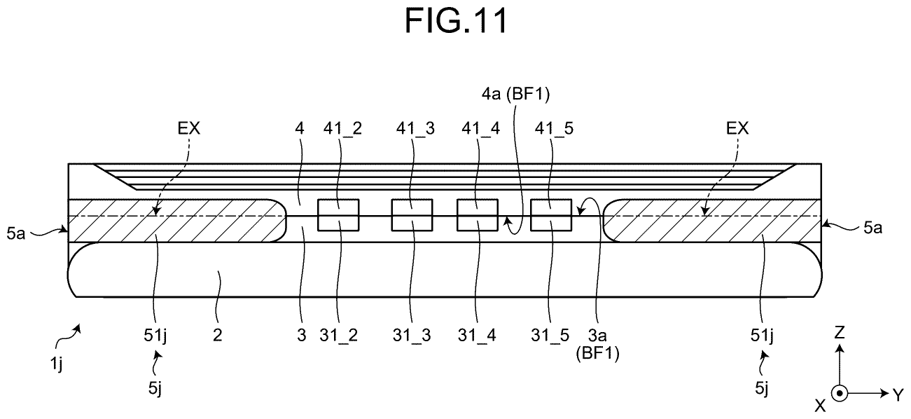

Alternatively, in the third modification of the embodiment, as illustrated in FIG. 11, an insulating member 5j may extend outward in the XY direction from positions corresponding to some electrodes, in a semiconductor device 1j. FIG. 11 is a cross-sectional view illustrating a configuration of the semiconductor device 1j according to the third modification of the embodiment.

The insulating member 5j includes a flat portion 51j instead of the flat portion 51 (see FIG. 1), and does not include the outer peripheral portion 52 (see FIG. 1). The flat portion 51j extends from an end of the bonded surface BF1 (i.e., the flat surfaces 3a and 4a) to the outer side surface 5a of the insulating member 5j along the extension plane EX. The end of the bonded surface BF1 corresponds to a position between the electrodes 41_1 and 41_6 (see FIG. 1) on the outer side in the XY direction and the electrodes 41_2 and 41_5 on the inner side in the XY direction. In other words, the flat portion 51j may extend outward from a position corresponding to some electrodes, that is, the electrodes 41_1 and 41_6.

The flat portion 51j has a Z thickness that is larger than the Z thickness of the device structure 3. The flat portion 51j may be in contact with the front surface 2a of the substrate portion 2. The flat portion 51j is similar to the flat portion 51 of the embodiment in that the Z thickness is uniform in the radial direction.

The device structure 4 may have the side surface 4e1 flat in the Z direction, instead of the inclined side surface 4e (see FIG. 1).

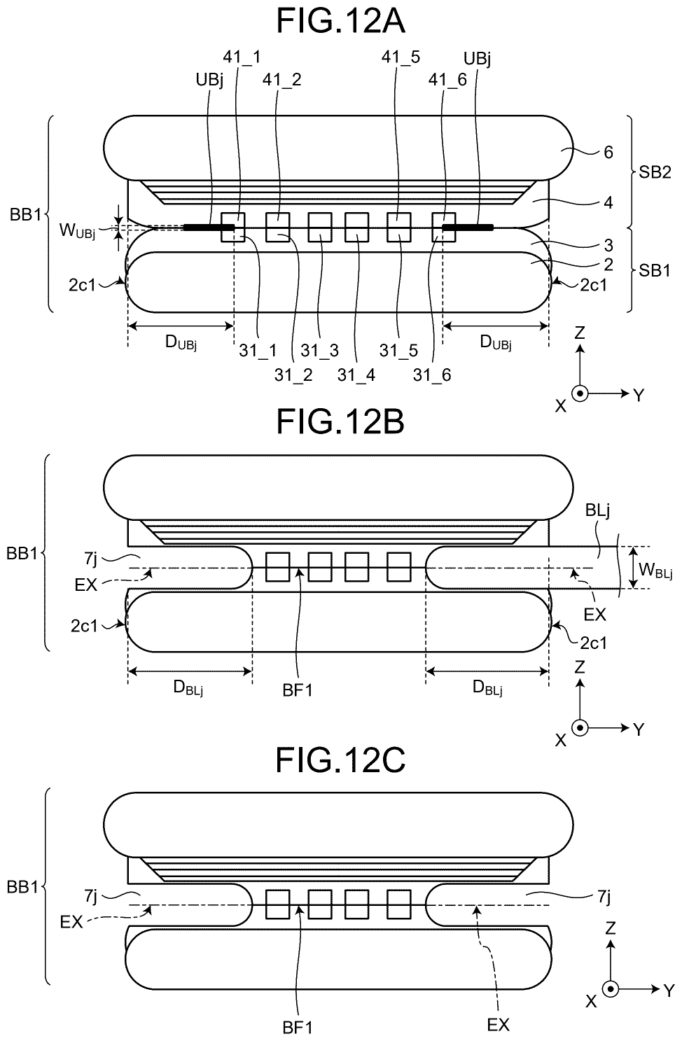

Furthermore, in a method of manufacturing the semiconductor device 1j, the steps of FIGS. 12A and 12B may be performed instead of the steps of FIGS. 3A and 3B.

In the step of FIG. 12A, the substrate SB1 and the substrate SB2 are brought closer to each other in the Z direction to bond the flat surface 3a and the flat surface 4a. Therefore, the bonded body BB1 in which the substrate SB1 and the substrate SB2 are bonded on the bonded surface BF1 is formed.

The unbonded area is measured for the bonded body BB1. The measurement of the unbonded area may be performed by the SAT. In the measurement of the unbonded area, the SAT image of the bonded body BB1 is acquired, and the SAT image is analyzed to measure the depth of the unbonded area in the XY direction. The depth of the unbonded area in the XY direction may be measured as the XY direction distance D_{UB} from the outer end 2c1 of the substrate portion 2 to the inner end of the unbonded area. A depth D_{UB} of the unbonded area in the XY direction is measured at multiple positions in a circumferential direction.

In the example of FIG. 12A, a result of the measurement for the unbonded area reaching some electrodes, that is, the electrodes 41_1 and 41_6 is exemplified. The depth D_{UB} of the unbonded area UB in the XY direction reaching the electrode 41_1 on the +Y side is measured, and the depth D_{UB} of the unbonded area UB in the XY direction reaching the electrode 41_6 on the −Y side is measured. The depth D_{UB} of the unbonded area in the XY direction may be obtained by selecting a maximum value from measured values at the multiple positions.

Note that the Z thickness W_{UB} of the unbonded area may be experimentally determined in advance, as the Z thickness of an unbonded area formed on average when multiple substrates is bonded.

In the step of FIG. 12B, according to a result of the measurement of the unbonded area, a groove 7j is formed inward from the outside along the bonded surface BF1 of the bonded body BB1 to remove the unbonded area. As illustrated in FIG. 12B, a groove 7j may be formed by cutting with a blade BLj.

A formation depth of the groove 7j may be determined as an XY direction distance D_{BLj} from the outer end 2c1 of the substrate portion 2 to the inner end of the unbonded area. A formation depth D_{BLj} of the groove 7j can be determined according to a depth D_{UBj} of the unbonded area in the XY direction measured in the step of FIG. 12A. As illustrated in FIG. 12B, a depth D_{BLj} of the groove 7j in the XY direction may be larger than the depth D_{UBj} of the unbonded area in the XY direction, and may be the XY direction distance D_{BLj} from the outer end 2c1 of the substrate portion 2 to a position between the electrode which the unbonded area reaches and another electrode positioned inward from the electrode.

The groove 7j has a formation thickness that is substantially equal to a Z thickness W_{BLj} of the blade BLj. As illustrated in FIG. 12B, a formation thickness W_{BLj} of the groove 7j may be larger than a Z thickness W_{UBj} of the unbonded area, and may be such a thickness that a surface of the blade BLj on the +Z side makes contact with the front surface 2a of the substrate portion 2. The formation thickness W_{BLj} of the groove 7j may have a value W_{BL} (=W31+W41+ΔW) obtained by adding the processing margin ΔW of the blade BL in the Z direction to the sum of a Z thickness W31 of the electrode 31 and a Z thickness W41 of the electrode 41.

The cutting device (not illustrated) rotates the bonded body BB1 around the Z axis in the direction RT1 (see FIG. 4), and rotates the blade BLj around the Z axis in the opposite direction RT2 (see FIG. 4). In this state, an area in the vicinity of the bonded surface BF1 including an unbonded area UBj is cut, while the blade BL is gradually brought closer to the center CP of the bonded body BB1, from outside the bonded surface BF1 in the XY direction. The cutting is performed until the tip of the blade BLj reaches an XY direction depth D_{BLj}. Therefore, as illustrated in FIG. 12C, the unbonded area UBj is removed, and the groove 7j internally including the extension plane EX of the bonded surface BF1 is formed.

In the semiconductor device 1j also configured in this manner, the flat portion 51j of the insulating member 5j is formed by embedding the insulating material into the groove formed by removing the unbonded area formed by bonding the two substrates, having a structure suitably configured to avoid failure caused by leaving the unbonded area as is. The flat portion 51j has a structure configured to support the device structures 3 and 4 in the bonded body BB upon manufacturing and appropriately support subsequent polishing and heat treatment of the bonded body BB. In other words, this structure also makes it possible to provide the semiconductor device 1j suitable for appropriate processing of the bonded body BB upon manufacturing.

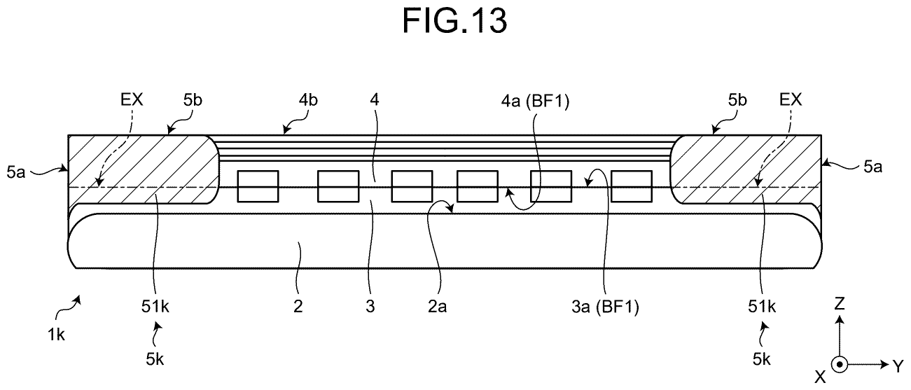

Alternatively, in the fourth modification of the embodiment, as illustrated in FIG. 13, an insulating member 5k may be configured to have a thickness corresponding to that of the device structure 4, in a semiconductor device 1k. FIG. 13 is a cross-sectional view illustrating a configuration of the semiconductor device 1k according to the fourth modification of the embodiment.

The insulating member 5k includes a flat portion 51k instead of the flat portion 51 (see FIG. 1) and does not include the outer peripheral portion 52 (see FIG. 1). The flat portion 51k extends from an end of the bonded surface BF1 (i.e., the flat surfaces 3a and 4a) to the outer side surface 5a of the insulating member 5k along the extension plane EX. The flat portion 51k has a Z thickness that corresponds to a Z thickness of the device structure 4. The Z thickness of the flat portion 51k may be larger than the Z thickness of the device structure 4. A flat surface 5b of the flat portion 51k on the +Z side may form a surface continued to the surface 4b of the device structure 4 on the +Z side. A height of the flat surface 5b of the flat portion 51k on the +Z side, from the front surface 2a may be equal to a height of the surface 4b of the device structure 4 on the +Z side, from the front surface 2a. The flat portion 51k is similar to the flat portion 51 of the embodiment in that the Z thickness is uniform in the radial direction. In a cross-sectional view, the flat portion 51k may have a rounded corner on the inner side in the XY direction and on the +Z side.

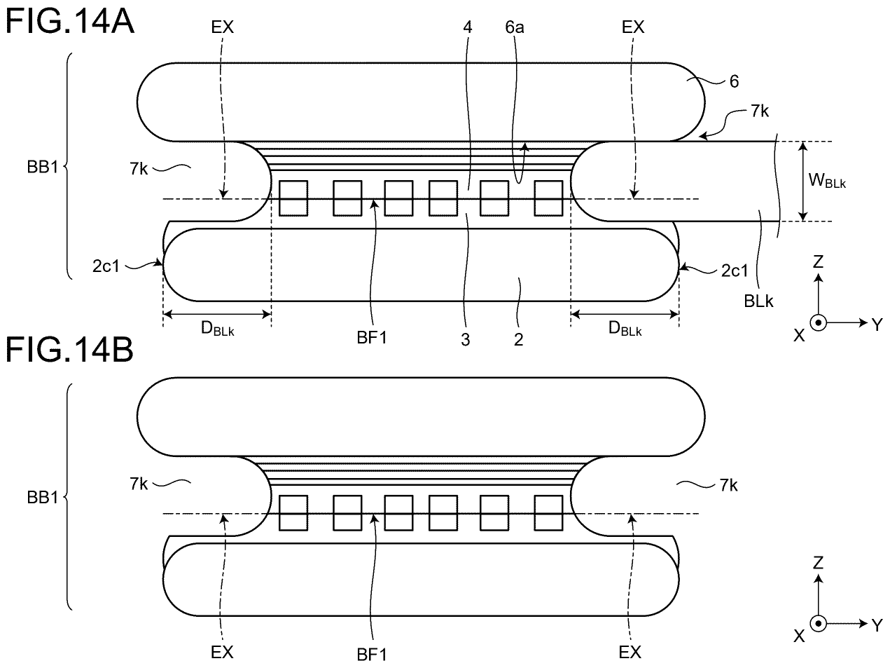

Furthermore, in a method of manufacturing the semiconductor device 1k, the step of FIG. 14A may be performed instead of the step of FIG. 3B.

In the step of FIG. 14A, according to a result of the measurement of the unbonded area (see FIG. 3A), a groove 7k is formed inward from the outside along the bonded surface BF1 of the bonded body BB1 to remove the unbonded area. As illustrated in FIG. 14A, the groove 7k may be formed by cutting with a blade BLk.

A formation depth of the groove 7k may be determined as an XY direction distance D_{BLk} from the outer end 2c1 of the substrate portion 2 to the inner end of the unbonded area. A formation depth D_{BLk} of the groove 7k can be determined according to the depth D_{UB} of the unbonded area in the XY direction measured in the step of FIG. 3A. As illustrated in FIG. 14A, a depth DELK of the groove 7k in the XY direction may be larger than the depth D_{UB} of the unbonded area in the XY direction, and may have a value D_{BLk} (=D_{UB}+ΔD) obtained by adding the processing margin ΔD of the blade BLk in the XY direction to the depth D_{UB} of the unbonded area in the XY direction.

The groove 7k has a formation thickness that is substantially equal to a Z thickness W_{BLk} of the blade BLk. As illustrated in FIG. 14A, a formation thickness W_{BLk} of the groove 7k may be larger than the Z thickness W_{UB} of the unbonded area, and may be such a thickness that a surface of the blade BLk on the +Z side makes contact with the front surface 6a of the substrate portion 6. The formation thickness W_{BLk} of the groove 7k may have a value W_{BLk} (=W_{UB}+W4+ΔW) obtained by adding a Z thickness W4 of the device structure 4 and the processing margin ΔW of the blade BLk in the Z direction to the Z thickness W_{UB} of the unbonded area.

The cutting device (not illustrated) rotates the bonded body BB1 around the Z axis in the direction RT1 (see FIG. 4), and rotates the blade BLk around the Z axis in the opposite direction RT2 (see FIG. 4). In this state, an area in the vicinity of the bonded surface BF1 including the unbonded area UB is cut, while the blade BL is gradually brought closer to a center CP of the bonded body BB1, from outside the bonded surface BF1 in the XY direction. The cutting is performed until the tip of the blade BLk reaches an XY depth DELK. Therefore, as illustrated in FIG. 14B, the unbonded area UB is removed, and the groove 7k internally including the extension plane EX of the bonded surface BF1 is formed.

In the semiconductor device 1k also configured in this manner, the flat portion 51k of the insulating member 5k is formed by embedding the insulating material into the groove 7k formed by removing the unbonded area formed by bonding the two substrates, having a structure suitably configured to avoid failure caused by leaving the unbonded area as is. The flat portion 51k has a structure configured to support the device structures 3 and 4 in the bonded body BB upon manufacturing and appropriately support subsequent polishing and heat treatment of the bonded body BB. In other words, this structure also makes it possible to provide the semiconductor device 1k suitable for appropriate processing of the bonded body BB upon manufacturing.

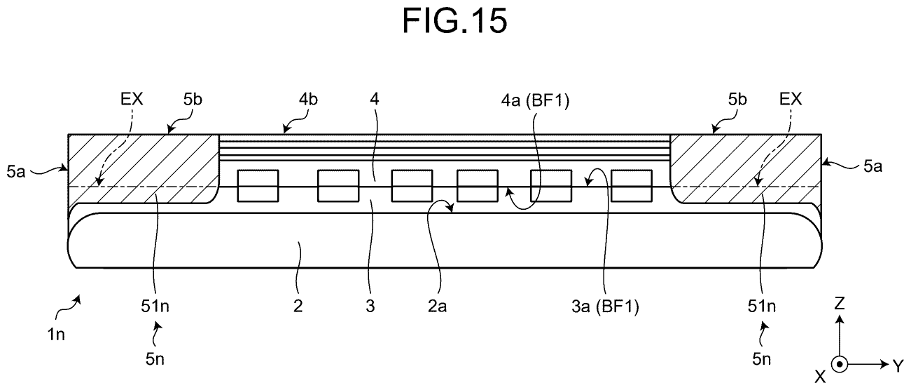

Alternatively, as the fifth modification of the embodiment, as illustrated in FIG. 15, an insulating member 5n may be configured to have a thickness corresponding to that of the device structure 4, in a semiconductor device 1n. FIG. 15 is a cross-sectional view illustrating a configuration of the semiconductor device 1n according to the fifth modification of the embodiment.

The insulating member 5n includes a flat portion 51n instead of the flat portion 51 (see FIG. 1) and does not include the outer peripheral portion 52 (see FIG. 1). The flat portion 51n extends from an end of the bonded surface BF1 (i.e., the flat surfaces 3a and 4a) to the outer side surface 5a of the insulating member 5n along the extension plane EX. The flat portion 51n has a Z thickness that corresponds to the Z thickness of the device structure 4. The Z thickness of the flat portion 51n may be larger than the Z thickness of the device structure 4. The flat surface 5b of the flat portion 51n on the +Z side may form a surface continued to the surface 4b of the device structure 4 on the +Z side. A height of the flat surface 5b of the flat portion 51n on the +Z side, from the front surface 2a may be equal to the height of the surface 4b of the device structure 4 on the +Z side, from the front surface 2a. The flat portion 51n is similar to the flat portion 51 of the embodiment in that the Z thickness is uniform in the radial direction. In a cross-sectional view, the flat portion 51n may have a substantially square corner on the inner side in the XY direction and on the +Z side.

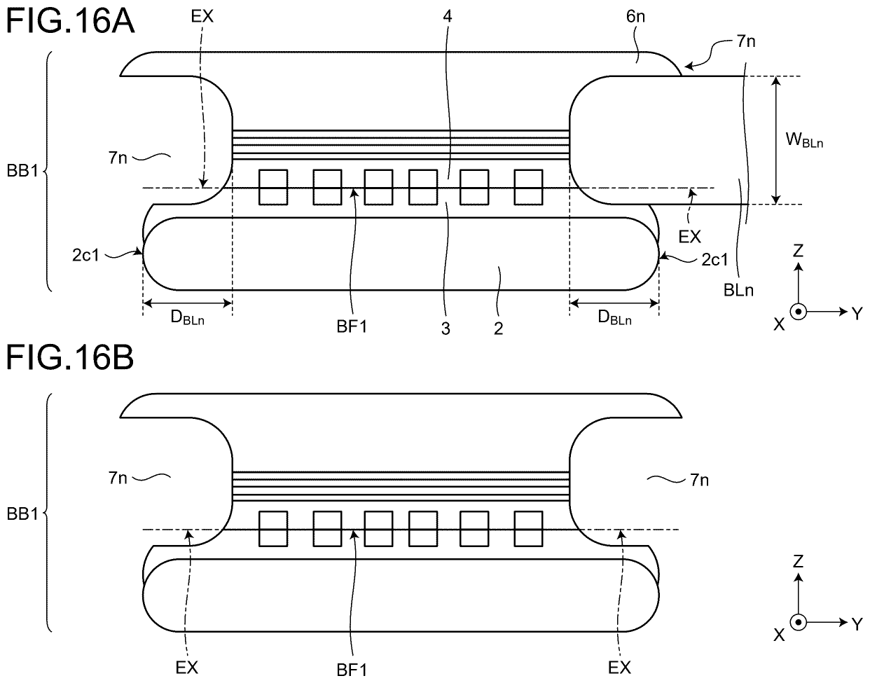

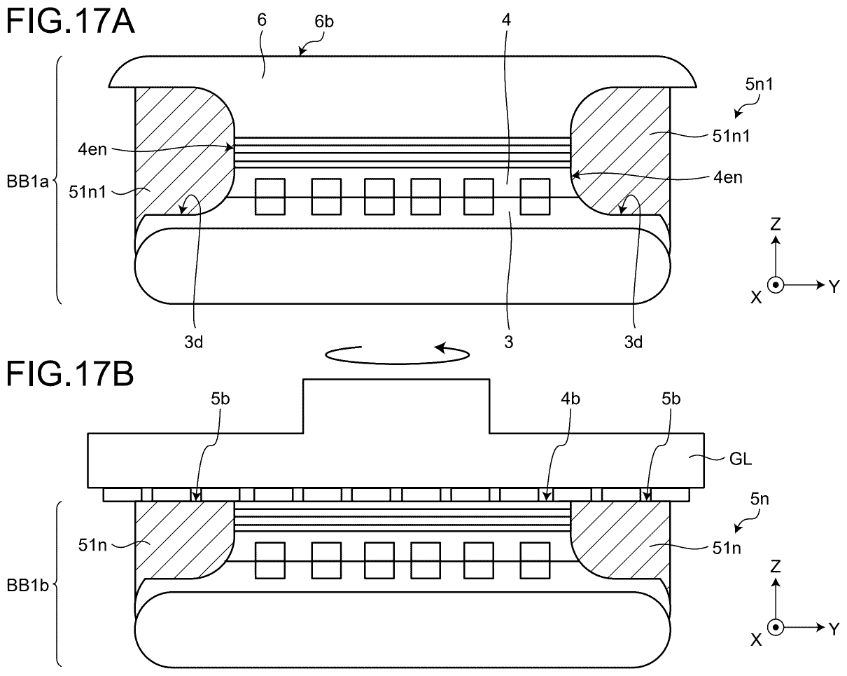

Furthermore, in a method of manufacturing the semiconductor device 1n, the steps of FIGS. 16A, 17A, and 17B may be performed instead of the steps of FIGS. 3B, 5B, 6A, and 6B.

In the step of FIG. 16A, according to a result of the measurement of the unbonded area (see FIG. 3A), a groove 7n is formed inward from the outside along the bonded surface BF1 of the bonded body BB1 to remove the unbonded area. As illustrated in FIG. 16A, the groove 7n may be formed by cutting with a blade BLn.

A formation depth of the groove 7n may be determined as an XY direction distance D_{BLn} from the outer end 2c1 of the substrate portion 2 to the inner end of the unbonded area. A formation depth D_{BLn} of the groove 7n can be determined according to the depth D_{UB} of the unbonded area in the XY direction measured in the step of FIG. 3A. As illustrated in FIG. 16A, a depth D_{BLn} of the groove 7n in the XY direction may be larger than the depth D_{UB} of the unbonded area in the XY direction, and may have a value D_{BLn} (=D_{UB}+ΔD) obtained by adding the processing margin ΔD of the blade BLn in the XY direction to the depth D_{UB} of the unbonded area in the XY direction.

The groove 7n has a formation thickness that is substantially equal to a Z thickness W_{BLn} of the blade BLn. As illustrated in FIG. 16A, a formation thickness W_{BLn} of the groove 7n may be larger than the Z thickness W_{UB} of the unbonded area, and may be such a thickness that a surface of the blade BLn on the +Z side is positioned in the substrate portion 6. The formation thickness W_{BLn} of the groove 7n may have a value W_{BLn} (=2×W4) that is approximately twice the Z thickness W4 of the device structure 4.

The cutting device (not illustrated) rotates the bonded body BB1 around the Z axis in the direction RT1 (see FIG. 4), and rotates the blade BLn around the Z axis in the opposite direction RT2 (see FIG. 4). In this state, an area in the vicinity of the bonded surface BF1 including the unbonded area UB is cut, while the blade BL is gradually brought closer to a center CP of the bonded body BB1, from outside the bonded surface BF1 in the XY direction. The cutting is performed until the tip of the blade BLn reaches an XY direction depth D_{BLn}. Therefore, as illustrated in FIG. 16B, the unbonded area UB is removed, and the groove 7n internally including the extension plane EX of the bonded surface BF1 is formed.

In the step of FIG. 17A, the insulating material is embedded into the groove 7n to form an insulating member 5n1.

The insulating material is embedded into the groove 7n to form a flat portion 51n1 flat in the XY direction. The insulating member 5n1 including the flat portion 51n1 is formed to make contact with the flat surface 3d of the device structure 3 and a side surface 4en of the device structure 4. This configuration forms the bonded body BB1a that is configured to support both the device structure 3 and the device structure 4 by the insulating member 5n1, on the outside of the bonded surface BF1 in the XY direction.

In the step illustrated in FIG. 17B, the grinder GL of the polisher is pressed against the back surface 6b of the substrate portion 6, and the grinder GL rotates about the axis perpendicular to the contact surface. Therefore, the substrate portion 6 is polished until the flat surface 4b of the device structure 4 is exposed, and at the same time, a portion of the insulating member 5n1 on the +Z side is also polished. As a result, the substrate portion 6 is removed off, and the flat surface 5b of the flat portion 51n on the +Z side is formed as a surface continued to the surface 4b of the device structure 4 on the +Z side. At this time, in the bonded body BB1b, the insulating member 5n supports both the device structure 3 and the device structure 4. Therefore, a portion in the vicinity of the outer end 3c of the device structure 3 and/or a portion in the vicinity of the outer end 4c of the device structure 4 is inhibited from being chipped, suppressing generation of the scrap pieces. In addition, presence of the insulating member 5n makes it possible to readily maintain the flatness of the flat surface 4b.

In the semiconductor device 1n also configured in this manner, the flat portion 51n of the insulating member 5n is formed by embedding the insulating material into the groove 7n formed by removing the unbonded area formed by bonding the two substrates, having a structure suitably configured to avoid failure caused by leaving the unbonded area as is. The flat portion 51n has a structure configured to support the device structures 3 and 4 in the bonded body BB upon manufacturing and appropriately support subsequent polishing and heat treatment of the bonded body BB. In other words, this structure also makes it possible to provide the semiconductor device 1n suitable for appropriate processing of the bonded body BB upon manufacturing.

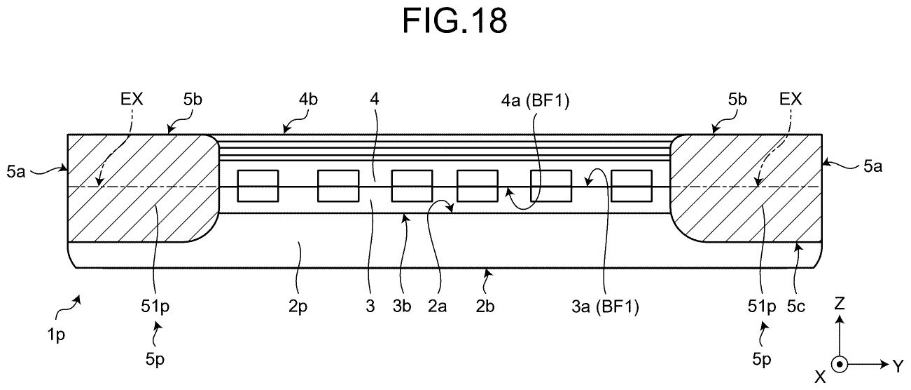

Alternatively, as the sixth modification of the embodiment, as illustrated in FIG. 18, an insulating member 5p may be configured to have a thickness corresponding to those of the device structure 3 and the device structure 4, in a semiconductor device 1p. FIG. 18 is a cross-sectional view illustrating a configuration of the semiconductor device 1p according to the sixth modification of the embodiment.

The insulating member 5p includes a flat portion 51p instead of the flat portion 51 (see FIG. 1) and does not include the outer peripheral portion 52 (see FIG. 1). The flat portion 51p extends from an end of the bonded surface BF1 (i.e., the flat surfaces 3a and 4a) to the outer side surface 5a of the insulating member 5p along the extension plane EX. The flat portion 51p has a Z thickness that corresponds to the Z thicknesses of the device structure 3 and the device structure 4. The Z thickness of the flat portion 51p may be larger than the sum of the Z thickness of the device structure 3 and the Z thickness of the device structure 4. The flat surface 5b of the flat portion 51p on the +Z side may form a surface continued to the surface 4b of the device structure 4 on the +Z side. A height of the flat surface 5b of the flat portion 51p on the +Z side, from the front surface 2a may be equal to the height of the surface 4b of the device structure 4 on the +Z side, from the front surface 2a. The flat portion 51p is similar to the flat portion 51 of the embodiment in that the Z thickness is uniform in the radial direction. A height of a flat surface 5c of the flat portion 51p on the −Z side, from the back surface 2b may be smaller than a height of the surface 3b of the device structure 3 on the −Z side, from the back surface 2b.

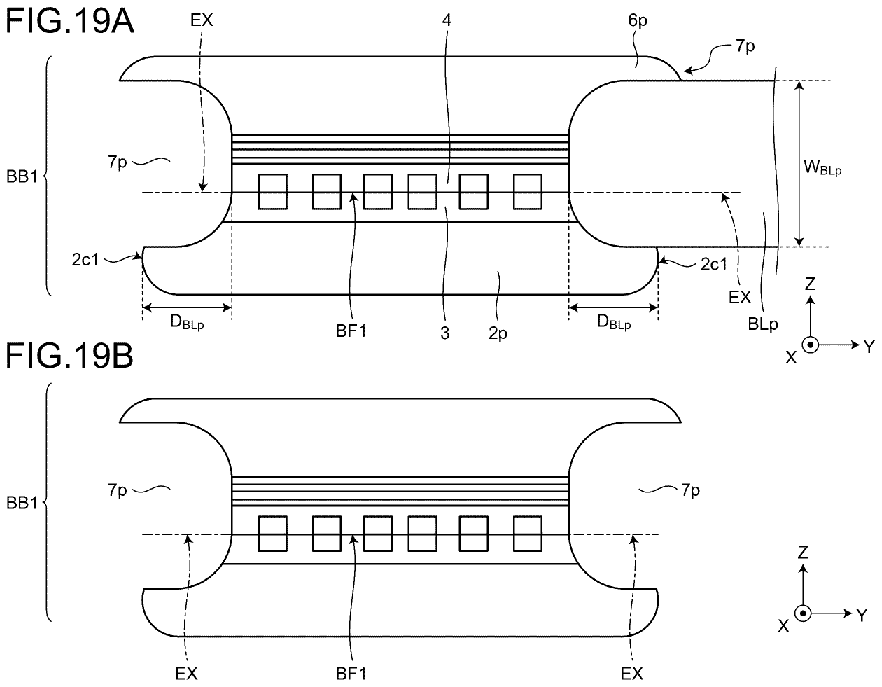

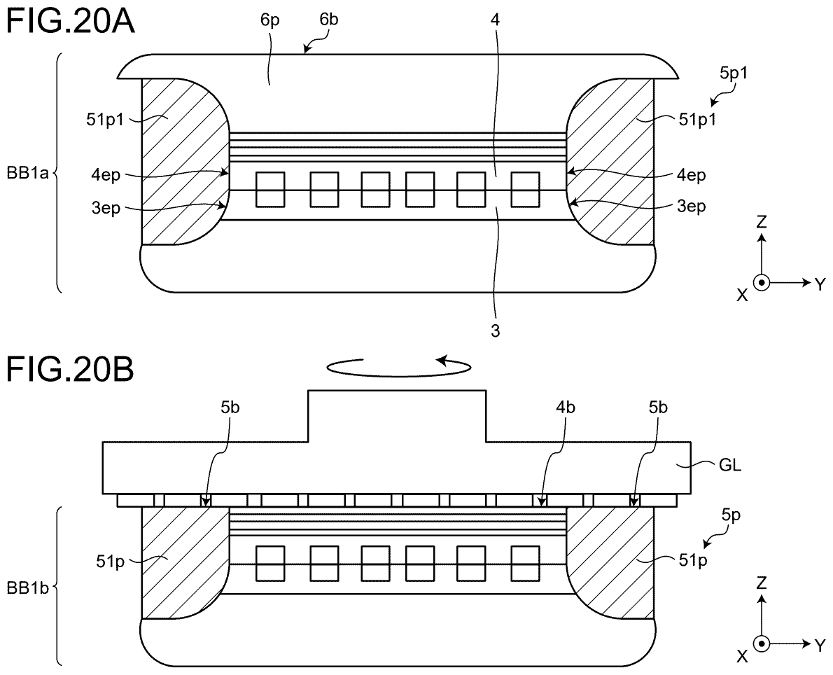

Furthermore, in a method of manufacturing the semiconductor device 1p, the steps of FIGS. 19A, 20A, and 20B may be performed instead of the steps of FIGS. 3B, 5B, 6A, and 6B.

In the step of FIG. 19A, according to a result of the measurement of the unbonded area (see FIG. 3A), a groove 7p is formed inward from the outside along the bonded surface BF1 of the bonded body BB1 to remove the unbonded area. As illustrated in FIG. 19A, the groove 7p may be formed by cutting with a blade BLp.

A formation depth of the groove 7p may be determined as an XY direction distance D_{BLp} from the outer end 2c1 of the substrate portion 2 to the inner end of the unbonded area. A formation depth D_{BLp} of the groove 7p can be determined according to the depth D_{UB} of the unbonded area in the XY direction measured in the step of FIG. 3A. As illustrated in FIG. 19A, a depth D_{BLp} of the groove 7p in the XY direction may be larger than the depth D_{UB} of the unbonded area in the XY direction, and may have a value D_{BLp} (=D_{UB}+ΔD) obtained by adding the processing margin ΔD of the blade BLp in the XY direction to the depth D_{UB} of the unbonded area in the XY direction.

The groove 7p has a formation thickness that is substantially equal to a Z thickness WELP of the blade BLp. As illustrated in FIG. 19A, a formation thickness W_{BLp} of the groove 7p may be larger than the Z thickness W_{UB} of the unbonded area, and may be such a thickness that a surface of the blade BLp on the +Z side is positioned in the substrate portion 6 and a surface of the blade BLp on the −Z side is positioned in the substrate portion 2. The formation thickness WELP of the groove 7p may have a value W_{BLp} (=2×(W3+W4)) that is approximately twice the sum of the Z thickness W3 of the device structure 3 and the Z thickness W4 of the device structure 4.

The cutting device (not illustrated) rotates the bonded body BB1 around the Z axis in the direction RT1 (see FIG. 4), and rotates the blade BLp around the Z axis in the opposite direction RT2 (see FIG. 4). In this state, an area in the vicinity of the bonded surface BF1 including the unbonded area UB is cut, while the blade BL is gradually brought closer to a center CP of the bonded body BB1, from outside the bonded surface BF1 in the XY direction. The cutting is performed until the tip of the blade BLp reaches an XY direction depth D_{BLp}. Therefore, as illustrated in FIG. 19B, the unbonded area UB is removed, and the groove 7p internally including the extension plane EX of the bonded surface BF1 is formed.

In the step of FIG. 20A, the insulating material is embedded into the groove 7p to form an insulating member 5p1.

The insulating material is embedded in the groove 7p to form a flat portion 51p1 flat in the XY direction. The insulating member 5p1 including the flat portion 51p1 is formed to make contact with a side surface 3ep of the device structure 3 and a side surface 4ep of the device structure 4. This configuration forms the bonded body BB1a that is configured to support both the device structure 3 and the device structure 4 by the insulating member 5p1, on the outside of the bonded surface BF1 in the XY direction.

In the step illustrated in FIG. 20B, the grinder GL of the polisher is pressed against the back surface 6b of the substrate portion 6, and the grinder GL rotates about the axis perpendicular to the contact surface. Therefore, the substrate portion 6 is polished until the flat surface 4b of the device structure 4 is exposed, and at the same time, a portion of the insulating member 5p1 on the +Z side is also polished. As a result, the substrate portion 6 is removed off, and the flat surface 5b of the flat portion 51p on the +Z side is formed as a surface continued to the surface 4b of the device structure 4 on the +Z side. At this time, in the bonded body BB1b, the insulating member 5p supports both the device structure 3 and the device structure 4. Therefore, a portion in the vicinity of the outer end 3c of the device structure 3 and/or a portion in the vicinity of the outer end 4c of the device structure 4 is inhibited from being chipped, suppressing generation of the scrap pieces. In addition, presence of the insulating member 5p makes it possible to readily maintain the flatness of the flat surface 4b.

In the semiconductor device 1p also configured in this manner, the flat portion 51p of the insulating member 5p is formed by embedding the insulating material into the groove 7p formed by removing the unbonded area formed by bonding the two substrates, having a structure suitably configured to avoid failure caused by leaving the unbonded area as is. The flat portion 51p has a structure configured to support the device structures 3 and 4 in the bonded body BB upon manufacturing and appropriately support subsequent polishing and heat treatment of the bonded body BB. In other words, this structure also makes it possible to provide the semiconductor device 1p suitable for appropriate processing of the bonded body BB upon manufacturing.

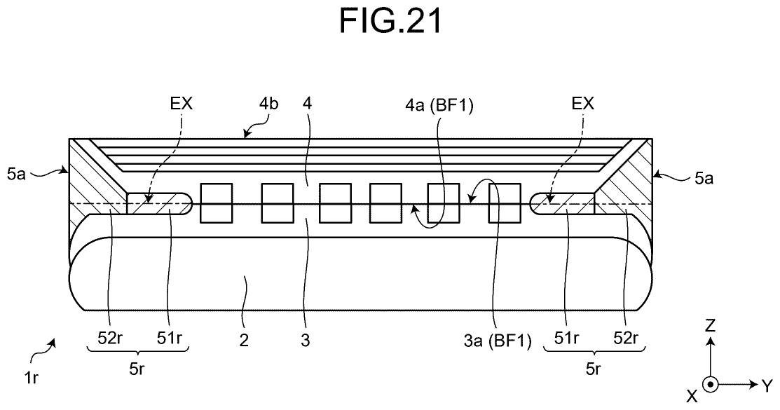

Alternatively, as the seventh modification of the embodiment, as illustrated in FIG. 21, an insulating member 5r may include multiple materials, in a semiconductor device 1r. FIG. 21 is a cross-sectional view illustrating a configuration of the semiconductor device 1r according to the seventh modification of the embodiment.

The insulating member 5r may contain two or more kinds of materials. A flat portion 51r may be formed of a first material, and an outer peripheral portion 52r may be formed of a second material. The first material and the second material may have different compositions, or may have the same composition with different film densities.

For example, the first material may have a viscosity lower than that of the second material. The second material may have a Young's modulus larger than that of the first material. The second material may have a tensile strength larger than that of the first material. As a result, the strength of the entire insulating member 5r can be secured while securing embeddability of the insulating material into the groove 7 upon manufacturing.

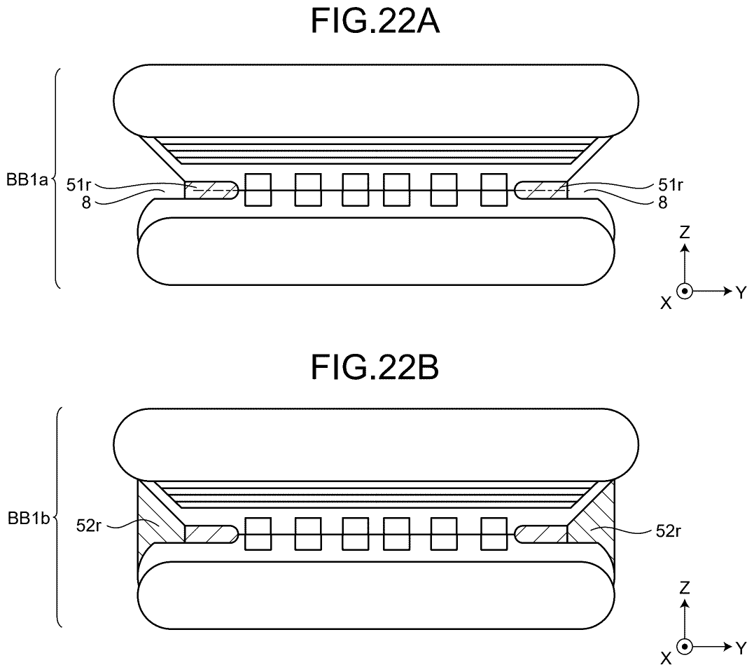

Furthermore, in a method of manufacturing the semiconductor device 1r, the steps of FIGS. 22A and 22B may be performed between the step of FIG. 5B and the step of FIG. 6A.

In the step of FIG. 5B, the first material as the insulating material is embedded into the groove 7 and the opening 8. For the first material, a material having relatively low viscosity may be used. Therefore, embeddability of the insulating material into the groove 7 can be secured, and the flat portion 51r can be appropriately formed.

The first material is embedded into the groove 7 to form the flat portion 51r flat in the XY direction. The first material is embedded into the opening 8 to form an outer peripheral portion 52r1 (not illustrated) having a substantially triangular shape in a cross-sectional view along the Z axis.

In the step of FIG. 22A, the first material embedded in the groove 7 and the opening 8 is etched back, the outer peripheral portion 52r1 embedded into the opening 8 is removed, and the flat portion 51r embedded in the groove 7 is selectively left. Therefore, as illustrated in FIG. 22A, the opening 8 is formed again outside the flat portion 51r in the XY direction.

In the step of FIG. 22B, the second material as the insulating material is embedded into the opening 8. For the second material, a material having a viscosity lower than that of the first material may be used. For the second material, a material having a Young's modulus larger than that of the first material may be used. For the second material, a material having a tensile strength larger than that of the first material may be used. Therefore, the strength of the outer peripheral portion 52r can be secured by the insulating material embedded into the opening 8.

The second material is embedded into the opening 8 to form the outer peripheral portion 52r having a substantially triangular shape in a cross-sectional view along the Z axis. As a result, the insulating member 5r including the flat portion 51r and the outer peripheral portion 52r is formed. The strength of the outer peripheral portion 52r can be secured, and therefore, the strength of the entire insulating member 5r can be secured.

In the step illustrated in FIG. 6A, the grinder GL of the polisher is pressed against the back surface 6b of the substrate portion 6, and the grinder GL rotates about the axis perpendicular to the contact surface. Therefore, the substrate portion 6 is thinned. At this time, the strength of the entire insulating member 5r can be secured in the bonded body BB1a′, and therefore, the insulating member 5r can reliably support both the device structure 3 and the device structure 4. Therefore, a portion in the vicinity of the outer end 3c of the device structure 3 and/or a portion in the vicinity of the outer end 4c of the device structure 4 is further inhibited from being chipped, further suppressing generation of the scrap pieces.

In the semiconductor device 1r also configured in this manner, the flat portion 51r of the insulating member 5r is formed by embedding the insulating material into the groove 7 formed by removing the unbonded area formed by bonding the two substrates, having a structure suitably configured to avoid failure caused by leaving the unbonded area as is. The flat portion 51r has a structure configured to support the device structures 3 and 4 in the bonded body BB upon manufacturing and appropriately support subsequent polishing and heat treatment of the bonded body BB. In other words, this structure also makes it possible to provide the semiconductor device 1r suitable for appropriate processing of the bonded body BB upon manufacturing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first device structure that has a first flat surface;
a second device structure that has a second flat surface bonded to the first flat surface; and
an insulating member that is arranged between an outer end of the first device structure and an outer end of the second device structure, the insulating member including a flat portion, the flat portion internally including an extension plane of the first flat surface and the second flat surface, the flat portion extending flat along the extension plane.

2. The semiconductor device according to claim 1, wherein
the insulating member makes contact with a vicinity of the outer end of the first device structure from a side of the second device structure, and makes contact with a vicinity of the outer end of the second device structure from a side of the first device structure.

3. The semiconductor device according to claim 1, wherein
the flat portion has a thickness uniform in a radial direction.

4. The semiconductor device according to claim 3, wherein
the thickness of the flat portion corresponds to a thickness of the first device structure.

5. The semiconductor device according to claim 3, wherein
the thickness of the flat portion corresponds to a thickness of the second device structure.

6. The semiconductor device according to claim 3, wherein
the thickness of the flat portion corresponds to thicknesses of the first device structure and the second device structure.

7. The semiconductor device according to claim 1, further comprising
a substrate portion that has a first main surface, wherein
the first device structure is arranged on the first main surface, and
a height of the flat portion from the first main surface is uniform in a radial direction.

8. The semiconductor device according to claim 1, wherein
the insulating member includes a first portion that includes a first material and a second portion that includes a second material.

9. The semiconductor device according to claim 8, wherein
the first portion includes the flat portion.

10. The semiconductor device according to claim 8, wherein
the first material has a viscosity lower than a viscosity of the second material.

11. The semiconductor device according to claim 8, wherein
the second material has a Young's modulus larger than a Young's modulus of the first material.

12. The semiconductor device according to claim 8, wherein
the second material has a tensile strength larger than a tensile strength of the first material.

13. The semiconductor device according to claim 1, wherein
the flat portion extends flat to an outer side surface of the insulating member along the first flat surface and the second flat surface.

14. The semiconductor device according to claim 13, further comprising
a substrate portion that has a first main surface, wherein
the first device structure is arranged on the first main surface, and
the flat portion is arranged on the first main surface on an outside of the first device structure.

15. The semiconductor device according to claim 14, wherein
the flat portion makes contact with the first main surface, on the outside of the first device structure.

16. The semiconductor device according to claim 14, wherein
the second device structure has a third flat surface, on an opposite side of the second flat surface, and
the flat portion has a fourth flat surface continued to the third flat surface.

17. A method of manufacturing a semiconductor device, comprising:
bonding a first flat surface of a first device structure of a first substrate and a second flat surface of a second substrate to form a bonded body, the first substrate including the first device structure and a substrate portion, the first device structure having the first flat surface, the second substrate including a second device structure and a substrate portion, the second device structure having the second flat surface;
forming a groove inward from an outside along a bonded surface of the bonded body; and
embedding an insulator into the groove.

18. The method of manufacturing a semiconductor device according to claim 17, further comprising:
measuring a depth of an unbonded area in a plane direction from an end of the first substrate; and
determining a depth of the groove in the plane direction from the end of the first substrate, according to the measured depth of the unbonded area in the plane direction, wherein
forming the groove includes
forming the groove inward from the outside along the bonded surface of the bonded body to have the determined width.

19. The method of manufacturing a semiconductor device according to claim 17, further comprising
removing off the substrate portion of the second substrate after the embedding.

20. The method of manufacturing a semiconductor device according to claim 17, wherein
the embedding includes
embedding a first insulator into a first portion of the groove, and
embedding a second insulator into a second portion outside the first portion of the groove.
